(19) United States
(12) Patent Application Publication
(10) Pub. No.: US 2014/0121145 A1
(43) Pub. Date: May 1, 2014

(54) TREATMENT OF SHAPED BODIES COMPRISING COPPER WITH A MIXTURE COMPRISING CHLORINE-FREE ACIDS AND OXIDIZING AGENT

(71) Applicant: BASF SE, Ludwigshafen (DE)

(72) Inventors: Thomas Paasche, Mannheim (DE); Henning Urch, Ludwigshafen (DE)

(73) Assignee: BASF SE, Ludwigshafen (DE)

(21) Appl. No.: 14/058,344

(22) Filed: Oct. 21, 2013

Related U.S. Application Data
(60) Provisional application No. 61/718,217, filed on Oct. 25, 2012.

(51) Int. Cl. H05K 3/06; C09K 13/00

(52) U.S. Cl. CPC H05K 3/067; C09K 13/00
USPC 510/175; 252/79.1; 205/291

(57) ABSTRACT

A process for treatment of shaped bodies comprising copper, wherein an aqueous mixture (M) comprising (a.) chlorine-free acids without carboxyl groups, (b.) oxidizing agents, (c.) aqueous solvent and optionally additional additives is contacted with the shaped body. Another characteristic feature of the process is that the aqueous mixture (M) after the etching or pickling additionally comprises (e.) dissolved copper and is separated from the solid. Also encompassed is a process for workup of the aqueous mixture (M) which has been separated and additionally comprises dissolved copper by electrolysis. Further provided are mixtures (MI) comprising (a.) from 10 to 40% by weight of methanesulfonic acid, (b.) from 10 to 20% by weight of hydrogen peroxide and (c.) from 40 to 80% by weight of water, and the use thereof for etching or pickling of shaped bodies comprising copper.

### DESCRIPTION

The present invention relates to a process for treatment of shaped bodies comprising copper with a mixture comprising chlorine-free acids without carboxyl groups and oxidizing agent. In addition, the invention also relates to mixtures comprising methanesulfonic acid and hydrogen peroxide. The invention further provides for the use of such mixtures comprising chlorine-free acids without carboxyl groups and oxidizing agent, especially methanesulfonic acid and hydrogen peroxide, for etching or pickling of shaped bodies comprising copper.

Further embodiments of the present invention can be inferred from the claims, description and examples. It will be appreciated that the features of the subject matter of the invention which have been specified above and are yet to be elucidated below can be used not just in the combination stated in each specific case but also in other combinations without leaving the scope of the invention. Preferred and very preferred embodiments of the present invention are those in which all features have the preferred and very preferred definitions.

Copper and copper alloys are frequently used as conductive materials in the field of semiconductor production. Copper tracks are frequently used as conductive connecting elements of semiconductor structures, for example in integrated circuits on printed circuit boards.

In the production of semiconductor structures, in various process steps, effective processes, for example wet-chemical etching techniques, are required for removal of copper or copper alloys. In this context, problems frequently occur since the removal of the copper is generally inhomogeneous and can lead to formation of unevenness at the surface or generally to problems with anisotropic removal at particle boundaries. For example, it is difficult to obtain smooth straight edges on isolated structures by homogeneous removal of copper. There is therefore a need for wet-chemical etching processes which lead to well-defined structures in the removal of copper-containing materials, more particularly to structures with smooth surfaces and defined edges.

In the wet-chemical removal of copper by etching, mixtures comprising acids, for example hydrochloric acid, acetic acid, sulfuric acid or nitric acid, and oxidizing agents such as peroxides, persulfates, permanganates, Fe(III) solutions, bromine or Cr(VI) compounds, are frequently used.

WO 2011/017119 A2 describes wet-chemical etching processes for removal of copper in the processing of semiconductors, with the aid of solutions comprising complexing agent and oxidizing agent within a pH range from 5 to 12.

U.S. 2005/0056616 A1 and US 2006/0183056 A1 describe processes for etching of copper and copper alloys. Compositions comprising weak and strong complexing agents for copper and oxidizing agent are used to treat the surfaces of copper or copper alloys at a pH of 6 to 12.

U.S. Pat. No. 7,465,408 B1 describes processes for etching of copper-containing materials, wherein the material is first contacted with a first solution which converts a portion of the material to a passivating layer. This first solution comprises a peroxide, a first organic acid and water at a pH of 2 to 6. Thereafter, the passivating coating is contacted with a second solution in order to remove the passivating film, this second solution comprising a second organic acid and water.

In the production of printed circuit boards, for example, copper is frequently deposited on to an epoxy resin sheet. A photoresist is applied to the copper layer and exposed selectively at particular sites. Unexposed residues of the photoresist are generally removed with alcoholic solutions in further processing steps. The copper layers which were below the unexposed photoresist then subsequently likewise have to be etched away, frequently by wet-chemical means.

Frequently, in industrial processes, aqueous mixtures of CuCl₂, FeCl₃ or HCl and hydrogen peroxide are used as etching mixtures for removal or formation of structures comprising copper or for pickling of surfaces comprising copper. The mixtures which result in these wet-chemical etching processes comprise, after the removal of the copper, as well as the copper ions, a high proportion of chloride ions in the solution and are therefore amenable only with difficulty to simple reprocessing and recovery of the copper, for example by electrolysis, owing to the formation of chlorine gas.

It was therefore an object of the present invention to find processes for treatment of shaped bodies comprising copper, which enable simple reprocessing and recovery of copper after the treatment. It was a further object of the invention to provide wet-chemical etching processes which lead to well-defined structures in the removal of copper-containing materials, especially to structures with smooth surfaces and defined edges.

These objects are achieved by a process for treatment, preferably for etching or pickling, of shaped bodies comprising copper, wherein an aqueous mixture (M) comprising (a.) chlorine-free acids without carboxyl groups, (b.) oxidizing agent and (c.) aqueous solvent is contacted with the shaped body.

The copper content of shaped bodies comprising copper may vary over a wide range according to the use of the shaped body. Frequently, for example, elaborated printed circuit boards comprise up to 25% by weight of pure copper. In other cases, the layer thickness of the copper is from 20 to 45 μm thick, which corresponds to about 0.02% by weight given an assumed total thickness of a printed circuit board of 1 mm. In the case of thinner circuit boards, the relative copper content thus generally rises.

In general, such shaped bodies comprise from 0.01% by weight to 50% by weight of copper, based on the total amount of shaped bodies. More preferably from 0.01 to 25% by weight. Additionally preferably, the copper occurs here in the form of metallic copper or of copper alloys with other metals, for example molybdenum.

In a preferred embodiment of the process according to the invention, the chlorine-free acids without carboxyl groups (a.) are selected from the group of the alkylsulfonic acids, tetrafluoroboric acid, sulfuric acid, hexafluorosilicic acid, trifluoroacetic acid, trifluoromethanesulfonic acid. Particular preference is given to methanesulfonic acid as the chlorine-free acid without carboxyl groups (a.).

In a further preferred embodiment of the process according to the invention, the oxidizing agents (b.) are selected from the group of the peroxide compounds and perborate compounds, preferably from the group consisting of hydrogen peroxide, sodium perborate, barium perborate, carbamate peroxide and urea peroxide, peroxocarboxylic acids such as performic acid or peracetic acid. Very particular preference is given to hydrogen peroxide as the oxidizing agent (b.).

Component (c.) comprises from 10 to 100% by weight of water as an aqueous solvent. The aqueous solvent (c.) used is preferably water. As well as water, further polar liquids such as alcohols, or ionic liquids, may be present in the aqueous solvent.

In a particularly preferred embodiment of the process according to the invention, the chlorine-free acids without a carboxyl group (a.) are alkylsulfonic acids, especially methanesulfonic acid, the oxidizing agent (b.) is hydrogen peroxide and the aqueous solvent (c.) is water.

The aqueous mixture (M) may comprise additional additives as a further component (d.). Preferred additives (d.) in this context include surfactants, complexing agents or corrosion inhibitors.

Surfactants serve here generally to improve the wetting of the shaped body or of the copper with the aqueous mixture (M). It is possible to use anionic, cationic, nonionic or amphoteric surfactants. The surfactants may also be polymeric surfactants and preferably have a block structure. Surfactants are known to those skilled in the art from the prior art and from their specialist knowledge and can be purchased commercially. Preference is given to using anionic or nonionic surfactants. For example, alkyl polyglycosides may be used as surfactants.

Complexing agents frequently serve to complex copper ions and hence accelerate the process of dissolving the copper. Corresponding complexing agents are known to those skilled in the art from the prior art and from their specialist knowledge and can be purchased commercially. For example, it is possible to use ethylenediaminetetraacetic acid (EDTA), methylglycinediacetic acid, glutamic acid diacetic acid (GLDA) or nitrilotriacetic acid (NTA) as complexing agents.

Corrosion inhibitors generally serve to prevent or to suppress unwanted corrosion effects on materials in the course of treatment of the shaped bodies comprising copper. Corresponding corrosion inhibitors are known to those skilled in the art from the prior art and from their specialist knowledge and can be purchased commercially. For example, it is possible to use alkyl phosphates, 2-butyne-1,4-diol, propargyl alcohol, ethynylcarbinol alkoxylate, polyethyleneimine, thiodiglycol ethoxylate as corrosion inhibitors.

In a further preferred embodiment of the process according to the invention, the aqueous mixture (M) comprises
(A.) from 10 to 40% by weight, preferably from 10 to 25% by weight, of the chlorine-free acids without carboxyl groups (a.),
(B.) from 1 to 50% by weight, preferably from 10 to 20% by weight, of the oxidizing agent (b.),
(C.) from 10 to 89% by weight, preferably from 55 to 80% by weight, of aqueous solvent (c.), and
(D.) from 0 to 10% by weight of the additional additives (d.),
   where the amounts are each based on the total amount of components (a.), (b.), (c.) and (d.) and the sum of the amounts of all components (a.), (b.), (c.) and (d.) is 100% by weight. More preferably, mixture (M), more particularly prior to the treatment of the shaped body, does not comprise any further components apart from components (a.), (b.), (c.) and optionally (d.).

The total amount of all additives (d.) in the aqueous mixture (M) is, as described above, in the range from 0 to 10% by weight, preferably from 0 to 5% by weight, especially from 0 to 3% by weight. Surfactants are used preferably in an amount of 0.5 to 2% by weight. Complexing agents are used preferably in an amount of 0.5 to 5% by weight. Corrosion inhibitors are used preferably in an amount of 0.1 to 1% by weight.

In general, the aqueous mixture (M) has a pH of −0.5 to 5, preferably of 0 to 5, more preferably of 0 to 3, even more preferably of 0 to 2, especially of 0 to 1. The pH of the mixture (M) is determined by means of a glass electrode.

In general, the copper present may be distributed as desired within the shaped body, provided that it is at least partly in contact or comes into contact or is contacted with the aqueous mixture (M). The copper present is preferably present at least partly at at least one surface of the shaped body. Most preferably as a flat layer on one side of the shaped body or on one or more further metal layers. More preferably on a layer comprising molybdenum.

The shaped body is preferably a printed circuit board or switchboard.

It has been found that, surprisingly, the etching times necessary in ₜhe process according to the invention were comparable to processes in which hydrochloric acid is used. It is therefore a further advantage of the process according to the invention that the chlorine-free acids without carboxyl groups, especially methanesulfonic acid, are much less corrosive than hydrochloric acid and nevertheless lead to short processing times and smooth straight surfaces and well-defined edges.

In the context of the process according to the invention for treatment of shaped bodies comprising copper, copper is generally removed from the shaped body, preference being given to separating metallic copper in the form of copper ions from the shaped body.

In a preferred embodiment of the process according to the invention, the aqueous mixture (M) after the treatment, preferably after the etching or pickling, additionally comprises dissolved copper, preferably in the form of copper ions, and the aqueous mixture is separated from the solid in a further process step. This affords what is called a waste solution.

The invention further provides a process for workup of the aqueous mixture (M) which additionally comprises (e.) dissolved copper (waste solution), wherein an electrolysis is performed on this waste solution in order to deposit at least some of the dissolved copper as metallic copper. Typical conditions for electrolytic production of copper on stainless steel electrodes are high current densities of 250-1000 A/m² at 0.3-0.4V. The electrode separation is 5 to 50 mm.

In this manner, it is possible to perform a simple and inexpensive process for recovering copper from the waste solutions. Since the chlorine-free acids without carboxyl groups do not comprise any chlorine, there is also no disruptive evolution of chlorine in the course of electrolysis. In general, it has been necessary to date for factories to transport their waste solutions to an external recycling or disposal company which will implement the recycling or disposal on its premises. With the aid of the process according to the invention, such factories are now actually able to inexpensively implement workup of their waste solutions internally, and to recover copper in the process.

The present invention further provides mixtures (MI) comprising (a.) from 10 to 40% by weight of methanesulfonic acid, (b.) from 10 to 20% by weight, preferably from 15 to 20% by weight, of hydrogen peroxide and (c.) from 40 to 80% by weight of water. These mixtures have outstanding usability with further additives (d.) too in the context of the process according to the invention for treatment of shaped bodies comprising copper. In general, from 0 to 10% by weight of additives (d.) is present in the mixtures. The amounts are each based on the total amount of components (a.), (b.), (c.) and optionally (d.), and the sum of the amounts of all components (a.), (b.), (c.), (d.) is 100% by weight.

More particularly, these inventive mixtures can be used for etching or pickling of shaped bodies comprising copper, the copper present preferably being present at least partly on at least one surface of the shaped body.

In a preferred embodiment of the inventive use, the shaped body is a printed circuit board.

The present invention provides processes for treatment of shaped bodies comprising copper, which enable simple reprocessing and recovery of copper after the treatment. Additionally provided are wet-chemical etching processes which lead to well-defined structures in the removal of copper-containing materials, especially to structures with smooth surfaces and defined edges.

The invention is illustrated in detail by the examples, but the examples do not limit the subject matter of the invention.

### EXAMPLES

The aqueous mixture M1 was obtained by mixing the individual components with water.

M1: 10% by weight of methanesulfonic acid (MSA), 15% by weight of H₂O₂, 75% by weight of H₂O.

As a comparative mixture C1, a mixture of 10% by weight of MSA and 90% by weight of H₂O was used.

### Example 1

### Measurement of the Polarization Resistance Rp

The determination of the polarization resistance was conducted within a potential range of ±5 mV against the corrosion potential (Ecorr) using a scan rate of 0.1 mV/s. The measured potential (E) plotted against the current density (j) was fitted to a straight line; the slope of the straight line was used to determine Rp.

The Rp indicates the resistance that a metal offers to the transfer of electrons to an electroactive species in solution. Higher values of Rp mean a higher corrosion resistance against homogeneous corrosion. Lower values thus correlate with faster dissolution of the metal.

### Dissolution of Copper:

For C1, within a period of 20 hours, Rp values of 2000 to 14 000 Ωcm² were determined, while mixture M1 already attained a value of 4 Ωcm² within a period of 50 minutes.

### Example 2

### Measurement of Potential

The measurements of potential (E: against reference cell, saturated calomel reference electrode (SCE)) against time or current density also show the distinct increase in the rate of copper dissolution for M1 compared to C1. The value of E for M1 is about +0.22 V, while about −0.5 V is attained for C1 within a period of up to 60 hours.

### Example 3

### Etching of Printed Circuit Boards

On copper-coated printed circuit boards (5×2 cm, copper layer thickness 45 μm, on epoxide plastic), a water-resistant pencil was used to draw geometric patterns.

The following aqueous comparative solutions (CS1-CS5) were prepared:

| CS1 | CS2 | CS3 | CS4 | CS5 |
|---|---|---|---|---|
| 18.5% HCl | 10% HCl | Ammonium | Ammonium | Iron(III) |
| 15% H2O2 | 15% H2O2 | persulfate | persulfate | chloride |
| | | solution | solution | solution |
| | | (150 g/l) | (300 g/l) | (220 g/l) |

In CS1 and CS2, the remainder to 100% by weight is water.

In addition, the following inventive aqueous solutions (S6-S15) were prepared:

| S6 | S7 | S8 | S9 | S10 |
|---|---|---|---|---|
| 35% MSA | 50% MSA | 27.2% HNO3 | 10% MSA | 15% MSA |
| 15% H2O2 | 15% H2O2 | 12% H2O2 | 15% H2O2 | 15% H2O2 |
| | | 20% MSA | | |

| S11 | S12 | S13 | S14 | S15 |
|---|---|---|---|---|
| 20% MSA | 25% MSA | 30% MSA | 35% MSA | 40% MSA |
| 15% H2O2 | 15% H2O2 | 15% H2O2 | 15% H2O2 | 15% H2O2 |

The remainder to 100% by weight in the case of S6 to S15 is water.

The copper-coated printed circuit boards were placed into 100 ml of the respective solution at a temperature of 18° C.

This gave the following dissolution times in minutes:

| CS1 | CS2 | CS3 | CS4 | CS5 | S6 | S7 | S8 | S9 | S10 | S11 | S12 | S13 | S14 | S15 |
|---|---|---|---|---|---|---|---|---|---|---|---|---|---|---|
| 10 | 12 | 50 | 50 | 50 | 12 | 12 | 12 | 24 | 24 | 12 | 12 | 12 | 12 | 12 |

After visual assessment of the dissolution, the experiment was ended after the appropriate time to prevent further oxidation of the copper.

The copper-coated printed circuit boards were additionally placed into 100 ml of the respective solution at a temperature of 18° C. for 12 to 50 minutes.

This gave the following view of the etching quality of the solutions:

| CS1 | CS2 | CS3 | CS4 | CS5 | S6 | S7 | S8 | S9 | S10 | S11 | S12 | S13 | S14 | S15 |
|---|---|---|---|---|---|---|---|---|---|---|---|---|---|---|
| ∘ | + | + | − | ∘ | ∘ | ∘ | − | + | ∘ | − | + | + | + | + |

This was a visual assessment of the etching quality. An assessment was made as to whether the geometric patterns after etching were of comparable clarity with CS1: o, better clarity: +, or poorer clarity: −.

1. A process for treating a shaped body, the process comprising: contacting an aqueous mixture with the shaped body,
wherein:
the shaped body comprises copper, and
the aqueous mixture comprises
(a) a chlorine-free acid without carboxyl groups,
(b) an oxidizing agent, and
(c) an aqueous solvent.

2. The process according to claim 1, wherein the aqueous mixture further comprises
(d) an additional additive.

3. The process according to claim 1, wherein the aqueous mixture comprises
from 10 to 40% by weight of the chlorine-free acid without carboxyl groups (a),
from 1 to 50% by weight of the oxidizing agent (b),
from 10 to 89% by weight of the aqueous solvent (c), and
from 0 to 10% by weight of an additional additives (d),
based on a total amount of components (a), (b), (c), and (d).

4. The process according to claim 1, wherein the aqueous mixture has a pH of from −0.5 to 5.

5. The process according to claim 1, wherein the copper is present at least partly on at least one surface of the shaped body and is contacted with the aqueous mixture.

6. The process according to claim 1, wherein the shaped body is a printed circuit board.

7. The process according to claim 1, wherein
the aqueous mixture after etching or pickling further comprises (e) dissolved copper, and
the aqueous mixture is separated from solid.

8. A process for working-up an aqueous mixture, the process comprising: performing an electrolysis in order to deposit at least some of dissolved copper as metallic copper after the aqueous mixture is separated from solid,
wherein the aqueous mixture comprises:
(a) a chlorine-free acid without carboxyl groups,
(b) an oxidizing agent,
(c) an aqueous solvent, and
(e) after etching or pickling, the dissolved copper.

9. A mixture comprising
(a) from 10 to 40% by weight of methanesulfonic acid,
(b) from 10 to 20% by weight of hydrogen peroxide, and
(c) from 40 to 80% by weight of water.

10. A process for etching or pickling a shaped body, the process comprising: applying the mixture according to claim 9 to a shaped body in need thereof,
wherein the shaped body comprises copper.

11. The process according to claim 10, wherein the copper is present at least partly on at least one surface of the shaped body.

12. The process according to claim 10, wherein the shaped body is a printed circuit board.
